(19) United States
(12) Patent Application Publication
(10) Pub. No.: US 2026/0153752 A1
(43) Pub. Date: Jun. 4, 2026

(54) MULTI-USE FLEXIBLE CIRCUIT FOR AN AUGMENTED-REALITY HEADSET

(71) Applicant: Meta Platforms Technologies, LLC, Menlo Park, CA (US)

(72) Inventors: Royce Dean Chang, Bothell, WA (US); Keith Murray Brown, Seattle, WA (US); Aaron Lee Heshelman, Seattle, WA (US)

(21) Appl. No.: 19/405,342

(22) Filed: Dec. 1, 2025

Related U.S. Application Data
(60) Provisional application No. 63/728,119, filed on Dec. 4, 2024.

(51) Int. Cl. G02C 11/00; H05K 1/02; G02B 27/01

(52) U.S. Cl. CPC G02C 11/10; H05K 1/0277; G02B 27/017; H05K 2201/10128

(57) ABSTRACT

A flex circuit of an augmented-reality headset is described. A shape of the flex circuit allows for placement of the flex circuit at a nose-bridge region of the augmented-reality headset. The flex circuit includes an image sensor that provides image data related to disparity between a first display and a second display of the augmented-reality headset, and circuitry used for charging a battery of the augmented-reality headset. The circuitry includes battery charging terminals that are located at the nose-bridge region of the augmented-reality headset.

### CROSS-REFERENCE TO RELATED APPLICATIONS

This application claims priority to U.S. Provisional Patent Application No. 63/728,119, filed December 4, 2024, entitled "Multi-Use Flexible Circuit For An Augmented-Reality Headset," which is incorporated herein by reference in its entirety.

### TECHNICAL FIELD

This relates generally to flexible circuits for an augmented-reality headset or a pair of smart glasses.

### BACKGROUND

Current devices include flexible circuits and associated circuit boards that are configured to perform a single function. Indeed, current devices rely on numerous circuits and/or circuit boards for each component within the device, which require a certain amount of space. This space is limited for augmented-reality headset. Accordingly, multiple single-function flexible circuits cannot be packaged within the available space of the augmented-reality headset, or the augmented-reality headset would increase to a size that is bulky, cumbersome, or generally uncomfortable for a user.

As such, there is a need to address one or more of the above-identified challenges. A brief summary of solutions to the issues noted above are described below.

### SUMMARY

One example of a flex circuit of an augmented-reality headset is described herein. This example flex circuit includes a shape that allows for the placement of the flex circuit at a nose bridge region of an augmented-reality headset, an image sensor configured to provide image data related to disparity between a first display and a second display of the augmented-reality headset, and circuitry used for charging a battery of the augmented-reality headset. The battery charging terminals of the circuitry are located at the nose bridge region of the augmented-reality headset.

The devices and/or systems described herein can be configured to include instructions that cause the performance of methods and operations associated with the presentation and/or interaction with an extended-reality (XR) headset. These methods and operations can be stored on a non-transitory computer-readable storage medium of a device or a system. It is also noted that the devices and systems described herein can be part of a larger, overarching system that includes multiple devices. A non-exhaustive of list of electronic devices that can, either alone or in combination (e.g., a system), include instructions that cause the performance of methods and operations associated with the presentation and/or interaction with an XR experience include an extended-reality headset (e.g., a mixed-reality (MR) headset or an augmented-reality (AR) headset as two examples), a wrist-wearable device, an intermediary processing device, a smart textile-based garment, etc. For example, when an XR headset is described, it is understood that the XR headset can be in communication with one or more other devices (e.g., a wrist-wearable device, a server, intermediary processing device) which together can include instructions for performing methods and operations associated with the presentation and/or interaction with an extended-reality system (i.e., the XR headset would be part of a system that includes one or more additional devices). Multiple combinations with different related devices are envisioned, but not recited for brevity.

The features and advantages described in the specification are not necessarily all inclusive and, in particular, certain additional features and advantages will be apparent to one of ordinary skill in the art in view of the drawings, specification, and claims. Moreover, it should be noted that the language used in the specification has been principally selected for readability and instructional purposes.

Having summarized the above example aspects, a brief description of the drawings will now be presented.

### BRIEF DESCRIPTION OF THE DRAWINGS

For a better understanding of the various described embodiments, reference should be made to the Detailed Description below, in conjunction with the following drawings in which like reference numerals refer to corresponding parts throughout the figures.

FIG. 1A illustrates an augmented-reality headset with a flexible circuit, including a zoomed-in view of a portion of the flexible circuit, in accordance with some embodiments.

FIG. 1B illustrates the flexible circuit including an intermediary ribbon cable, in accordance with some embodiments.

FIG. 1C illustrates a hot bar connection of the flexible circuit, in accordance with some embodiments.

FIGS. 2A, 2B, 2C-1, and 2C-2 illustrate example MR and AR systems, in accordance with some embodiments.

In accordance with common practice, the various features illustrated in the drawings may not be drawn to scale. Accordingly, the dimensions of the various features may be arbitrarily expanded or reduced for clarity. In addition, some of the drawings may not depict all of the components of a given system, method, or device. Finally, like reference numerals may be used to denote like features throughout the specification and figures.

### DETAILED DESCRIPTION

Numerous details are described herein to provide a thorough understanding of the example embodiments illustrated in the accompanying drawings. However, some embodiments may be practiced without many of the specific details, and the scope of the claims is only limited by those features and aspects specifically recited in the claims. Furthermore, well-known processes, components, and materials have not necessarily been described in exhaustive detail so as to avoid obscuring pertinent aspects of the embodiments described herein.

### Overview

Embodiments of this disclosure can include or be implemented in conjunction with various types of extended-realities (XRs) such as mixed-reality (MR) and augmented-reality (AR) systems. MRs and ARs, as described herein, are any superimposed functionality and/or sensory-detectable presentation provided by MR and AR systems within a user’s physical surroundings. Such MRs can include and/or represent virtual realities (VRs) and VRs in which at least some aspects of the surrounding environment are reconstructed within the virtual environment (e.g., displaying virtual reconstructions of physical objects in a physical environment to avoid the user colliding with the physical objects in a surrounding physical environment). In the case of MRs, the surrounding environment that is presented through a display is captured via one or more sensors configured to capture the surrounding environment (e.g., a camera sensor, time-of-flight (ToF) sensor). While a wearer of an MR headset can see the surrounding environment in full detail, they are seeing a reconstruction of the environment reproduced using data from the one or more sensors (i.e., the physical objects are not directly viewed by the user). An MR headset can also forgo displaying reconstructions of objects in the physical environment, thereby providing a user with an entirely VR experience. An AR system, on the other hand, provides an experience in which information is provided, e.g., through the use of a waveguide, in conjunction with the direct viewing of at least some of the surrounding environment through a transparent or semi-transparent waveguide(s) and/or lens(es) of the AR headset. Throughout this application, the term “extended reality (XR)” is used as a catchall term to cover both ARs and MRs. In addition, this application also uses, at times, a head-wearable device or headset device as a catchall term that covers XR headsets such as AR headsets and MR headsets.

As alluded to above, an MR environment, as described herein, can include, but is not limited to, non-immersive, semi-immersive, and fully immersive VR environments. As also alluded to above, AR environments can include marker-based AR environments, markerless AR environments, location-based AR environments, and projection-based AR environments. The above descriptions are not exhaustive and any other environment that allows for intentional environmental lighting to pass through to the user would fall within the scope of an AR, and any other environment that does not allow for intentional environmental lighting to pass through to the user would fall within the scope of an MR.

The AR and MR content can include video, audio, haptic events, sensory events, or some combination thereof, any of which can be presented in a single channel or in multiple channels (such as stereo video that produces a three-dimensional effect to a viewer). Additionally, AR and MR can also be associated with applications, products, accessories, services, or some combination thereof, which are used, for example, to create content in an AR or MR environment and/or are otherwise used in (e.g., to perform activities in) AR and MR environments.

Interacting with these AR and MR environments described herein can occur using multiple different modalities and the resulting outputs can also occur across multiple different modalities. In one example AR or MR system, a user can perform a swiping in-air hand gesture to cause a song to be skipped by a song-providing application programming interface (API) providing playback at, for example, a home speaker.

A hand gesture, as described herein, can include an in-air gesture, a surface-contact gesture, and or other gestures that can be detected and determined based on movements of a single hand (e.g., a one-handed gesture performed with a user’s hand that is detected by one or more sensors of a wearable device (e.g., electromyography (EMG) and/or inertial measurement units (IMUs) of a wrist-wearable device, and/or one or more sensors included in a smart textile wearable device) and/or detected via image data captured by an imaging device of a wearable device (e.g., a camera of a head-wearable device, an external tracking camera setup in the surrounding environment)). “In-air” generally includes gestures in which the user’s hand does not contact a surface, object, or portion of an electronic device (e.g., a head-wearable device or other communicatively coupled device, such as the wrist-wearable device), in other words the gesture is performed in open air in 3D space and without contacting a surface, an object, or an electronic device. Surface-contact gestures (contacts at a surface, object, body part of the user, or electronic device) more generally are also contemplated in which a contact (or an intention to contact) is detected at a surface (e.g., a single- or double-finger tap on a table, on a user’s hand or another finger, on the user’s leg, a couch, a steering wheel). The different hand gestures disclosed herein can be detected using image data and/or sensor data (e.g., neuromuscular signals sensed by one or more biopotential sensors (e.g., EMG sensors) or other types of data from other sensors, such as proximity sensors, ToF sensors, sensors of an IMU, capacitive sensors, strain sensors) detected by a wearable device worn by the user and/or other electronic devices in the user’s possession (e.g., smartphones, laptops, imaging devices, intermediary devices, and/or other devices described herein).

The input modalities as alluded to above can be varied and are dependent on a user’s experience. For example, in an interaction in which a wrist-wearable device is used, a user can provide inputs using in-air or surface-contact gestures that are detected using neuromuscular signal sensors of the wrist-wearable device. In the event that a wrist-wearable device is not used, alternative and entirely interchangeable input modalities can be used instead, such as camera(s) located on the headset or elsewhere to detect in-air or surface-contact gestures or inputs at an intermediary processing device (e.g., through physical input components (e.g., buttons and trackpads)). These different input modalities can be interchanged based on both desired user experiences, portability, and/or a feature set of the product (e.g., a low-cost product may not include hand-tracking cameras).

While the inputs are varied, the resulting outputs stemming from the inputs are also varied. For example, an in-air gesture input detected by a camera of a head-wearable device can cause an output to occur at a head-wearable device or control another electronic device different from the head-wearable device. In another example, an input detected using data from a neuromuscular signal sensor can also cause an output to occur at a head-wearable device or control another electronic device different from the head-wearable device. While only a couple examples are described above, one skilled in the art would understand that different input modalities are interchangeable along with different output modalities in response to the inputs.

Specific operations described above may occur as a result of specific hardware. The devices described are not limiting and features on these devices can be removed or additional features can be added to these devices. The different devices can include one or more analogous hardware components. For brevity, analogous devices and components are described herein. Any differences in the devices and components are described below in their respective sections.

As described herein, a processor (e.g., a central processing unit (CPU) or microcontroller unit (MCU)), is an electronic component that is responsible for executing instructions and controlling the operation of an electronic device (e.g., a wrist-wearable device, a head-wearable device, a handheld intermediary processing device (HIPD), a smart textile-based garment, or other computer system). There are various types of processors that may be used interchangeably or specifically required by embodiments described herein. For example, a processor may be (i) a general processor designed to perform a wide range of tasks, such as running software applications, managing operating systems, and performing arithmetic and logical operations; (ii) a microcontroller designed for specific tasks such as controlling electronic devices, sensors, and motors; (iii) a graphics processing unit (GPU) designed to accelerate the creation and rendering of images, videos, and animations (e.g., VR animations, such as three-dimensional modeling); (iv) a field-programmable gate array (FPGA) that can be programmed and reconfigured after manufacturing and/or customized to perform specific tasks, such as signal processing, cryptography, and machine learning; or (v) a digital signal processor (DSP) designed to perform mathematical operations on signals such as audio, video, and radio waves. One of skill in the art will understand that one or more processors of one or more electronic devices may be used in various embodiments described herein.

As described herein, controllers are electronic components that manage and coordinate the operation of other components within an electronic device (e.g., controlling inputs, processing data, and/or generating outputs). Examples of controllers can include (i) microcontrollers, including small, low-power controllers that are commonly used in embedded systems and Internet of Things (IoT) devices; (ii) programmable logic controllers (PLCs) that may be configured to be used in industrial automation systems to control and monitor manufacturing processes; (iii) system-on-a-chip (SoC) controllers that integrate multiple components such as processors, memory, I/O interfaces, and other peripherals into a single chip; and/or (iv) DSPs. As described herein, a graphics module is a component or software module that is designed to handle graphical operations and/or processes and can include a hardware module and/or a software module.

As described herein, memory refers to electronic components in a computer or electronic device that store data and instructions for the processor to access and manipulate. The devices described herein can include volatile and non-volatile memory. Examples of memory can include (i) random access memory (RAM), such as DRAM, SRAM, DDR RAM or other random access solid state memory devices, configured to store data and instructions temporarily; (ii) read-only memory (ROM) configured to store data and instructions permanently (e.g., one or more portions of system firmware and/or boot loaders); (iii) flash memory, magnetic disk storage devices, optical disk storage devices, other non-volatile solid state storage devices, which can be configured to store data in electronic devices (e.g., universal serial bus (USB) drives, memory cards, and/or solid-state drives (SSDs)); and (iv) cache memory configured to temporarily store frequently accessed data and instructions. Memory, as described herein, can include structured data (e.g., SQL databases, MongoDB databases, GraphQL data, or JSON data). Other examples of memory can include (i) profile data, including user account data, user settings, and/or other user data stored by the user; (ii) sensor data detected and/or otherwise obtained by one or more sensors; (iii) media content data including stored image data, audio data, documents, and the like; (iv) application data, which can include data collected and/or otherwise obtained and stored during use of an application; and/or (v) any other types of data described herein.

As described herein, a power system of an electronic device is configured to convert incoming electrical power into a form that can be used to operate the device. A power system can include various components, including (i) a power source, which can be an alternating current (AC) adapter or a direct current (DC) adapter power supply; (ii) a charger input that can be configured to use a wired and/or wireless connection (which may be part of a peripheral interface, such as a USB, micro-USB interface, near-field magnetic coupling, magnetic inductive and magnetic resonance charging, and/or radio frequency (RF) charging); (iii) a power-management integrated circuit, configured to distribute power to various components of the device and ensure that the device operates within safe limits (e.g., regulating voltage, controlling current flow, and/or managing heat dissipation); and/or (iv) a battery configured to store power to provide usable power to components of one or more electronic devices.

As described herein, peripheral interfaces are electronic components (e.g., of electronic devices) that allow electronic devices to communicate with other devices or peripherals and can provide a means for input and output of data and signals. Examples of peripheral interfaces can include (i) USB and/or micro-USB interfaces configured for connecting devices to an electronic device; (ii) Bluetooth interfaces configured to allow devices to communicate with each other, including Bluetooth low energy (BLE); (iii) near-field communication (NFC) interfaces configured to be short-range wireless interfaces for operations such as access control; (iv) pogo pins, which may be small, spring-loaded pins configured to provide a charging interface; (v) wireless charging interfaces; (vi) global-positioning system (GPS) interfaces; (vii) Wi-Fi interfaces for providing a connection between a device and a wireless network; and (viii) sensor interfaces.

As described herein, sensors are electronic components (e.g., in and/or otherwise in electronic communication with electronic devices, such as wearable devices) configured to detect physical and environmental changes and generate electrical signals. Examples of sensors can include (i) imaging sensors for collecting imaging data (e.g., including one or more cameras disposed on a respective electronic device, such as a simultaneous localization and mapping (SLAM) camera); (ii) biopotential-signal sensors; (iii) IMUs for detecting, for example, angular rate, force, magnetic field, and/or changes in acceleration; (iv) heart rate sensors for measuring a user’s heart rate; (v) peripheral oxygen saturation (SpO₂) sensors for measuring blood oxygen saturation and/or other biometric data of a user; (vi) capacitive sensors for detecting changes in potential at a portion of a user’s body (e.g., a sensor-skin interface) and/or the proximity of other devices or objects; (vii) sensors for detecting some inputs (e.g., capacitive and force sensors); and (viii) light sensors (e.g., ToF sensors, infrared light sensors, or visible light sensors), and/or sensors for sensing data from the user or the user’s environment. As described herein biopotential-signal-sensing components are devices used to measure electrical activity within the body (e.g., biopotential-signal sensors). Some types of biopotential-signal sensors include (i) electroencephalography (EEG) sensors configured to measure electrical activity in the brain to diagnose neurological disorders; (ii) electrocardiography (ECG or EKG) sensors configured to measure electrical activity of the heart to diagnose heart problems; (iii) EMG sensors configured to measure the electrical activity of muscles and diagnose neuromuscular disorders; (iv) electrooculography (EOG) sensors configured to measure the electrical activity of eye muscles to detect eye movement and diagnose eye disorders.

As described herein, an application stored in memory of an electronic device (e.g., software) includes instructions stored in the memory. Examples of such applications include (i) games; (ii) word processors; (iii) messaging applications; (iv) media-streaming applications; (v) financial applications; (vi) calendars; (vii) clocks; (viii) web browsers; (ix) social media applications; (x) camera applications; (xi) web-based applications; (xii) health applications; (xiii) AR and MR applications; and/or (xiv) any other applications that can be stored in memory. The applications can operate in conjunction with data and/or one or more components of a device or communicatively coupled devices to perform one or more operations and/or functions.

As described herein, communication interface modules can include hardware and/or software capable of data communications using any of a variety of custom or standard wireless protocols (e.g., IEEE 802.15.4, Wi-Fi, ZigBee, 6LoWPAN, Thread, Z-Wave, Bluetooth Smart, ISA100.11a, WirelessHART, or MiWi), custom or standard wired protocols (e.g., Ethernet or HomePlug), and/or any other suitable communication protocol, including communication protocols not yet developed as of the filing date of this document. A communication interface is a mechanism that enables different systems or devices to exchange information and data with each other, including hardware, software, or a combination of both hardware and software. For example, a communication interface can refer to a physical connector and/or port on a device that enables communication with other devices (e.g., USB, Ethernet, HDMI, or Bluetooth). A communication interface can refer to a software layer that enables different software programs to communicate with each other (e.g., APIs and protocols such as HTTP and TCP/IP).

As described herein, a graphics module is a component or software module that is designed to handle graphical operations and/or processes and can include a hardware module and/or a software module.

As described herein, non-transitory computer-readable storage media are physical devices or storage medium that can be used to store electronic data in a non-transitory form (e.g., such that the data is stored permanently until it is intentionally deleted and/or modified).

### Flexible Circuit for Augmented-Reality Glasses

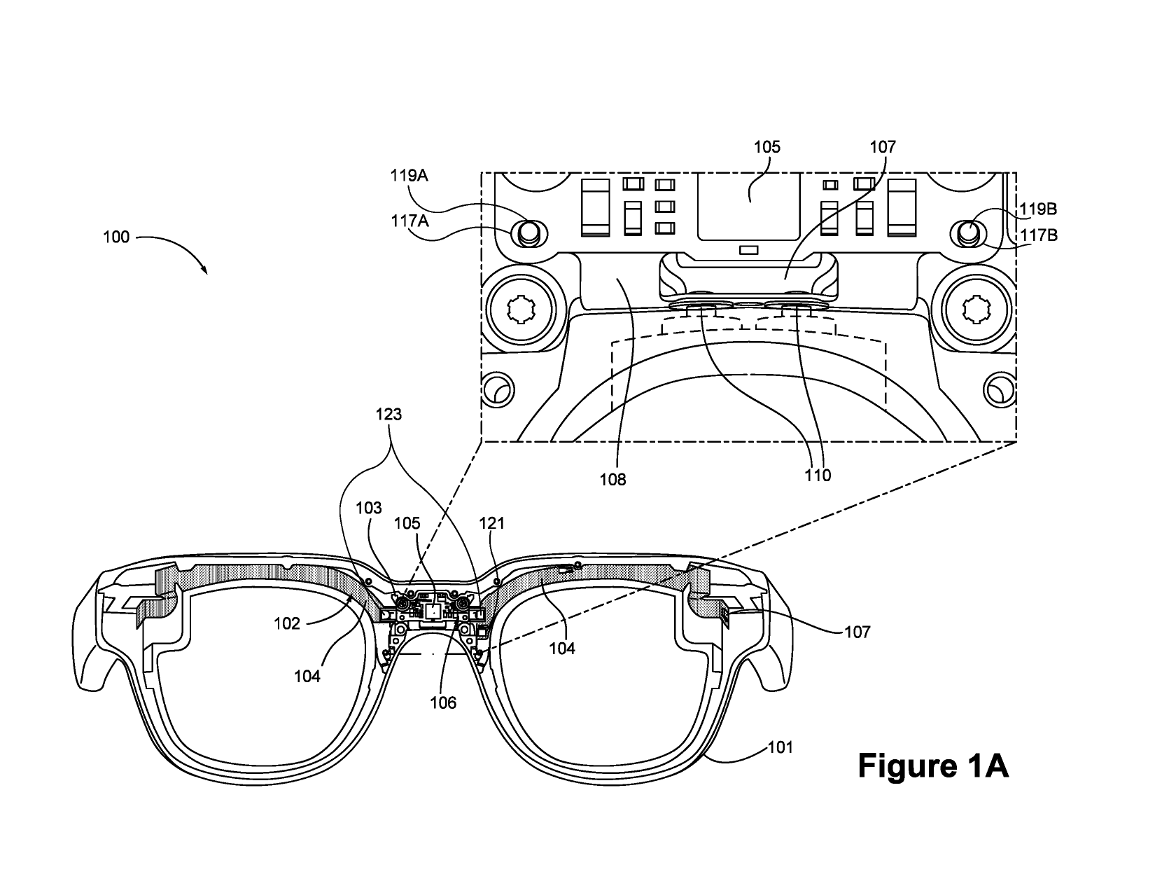

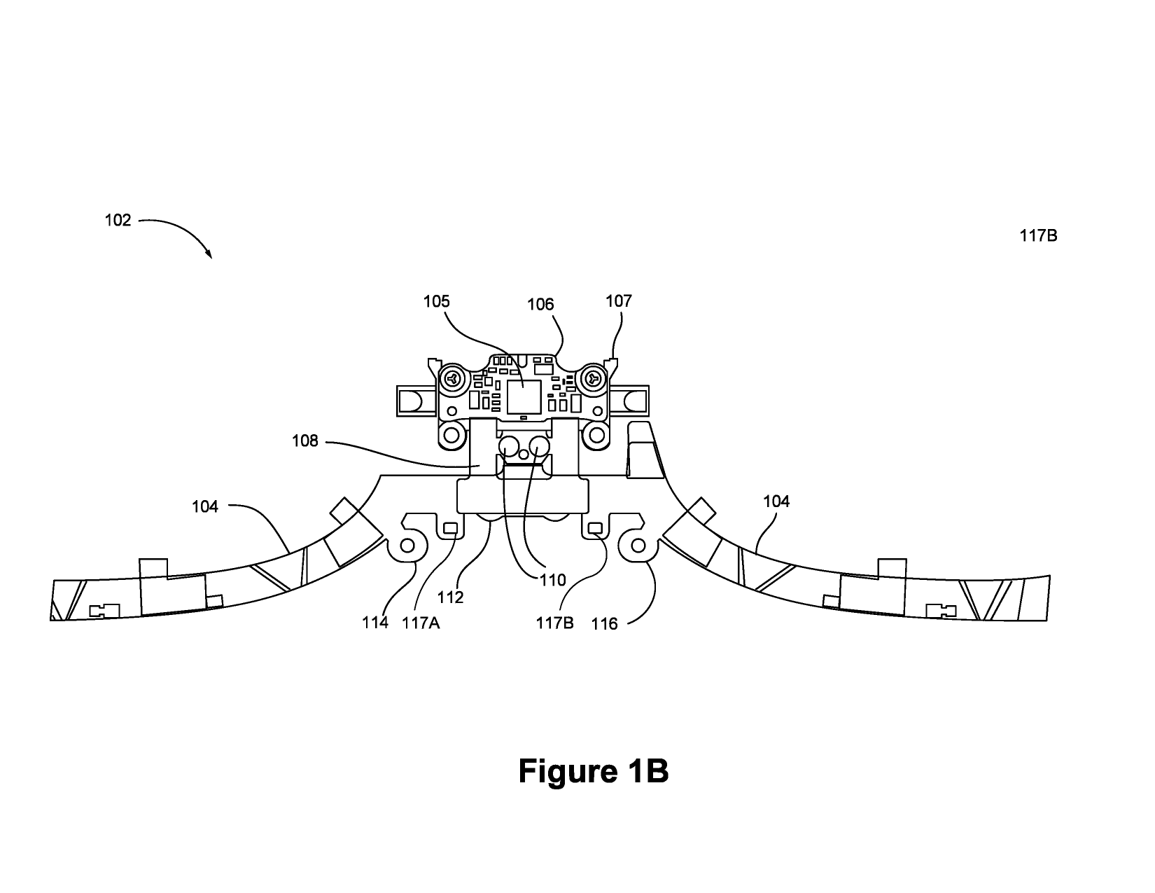

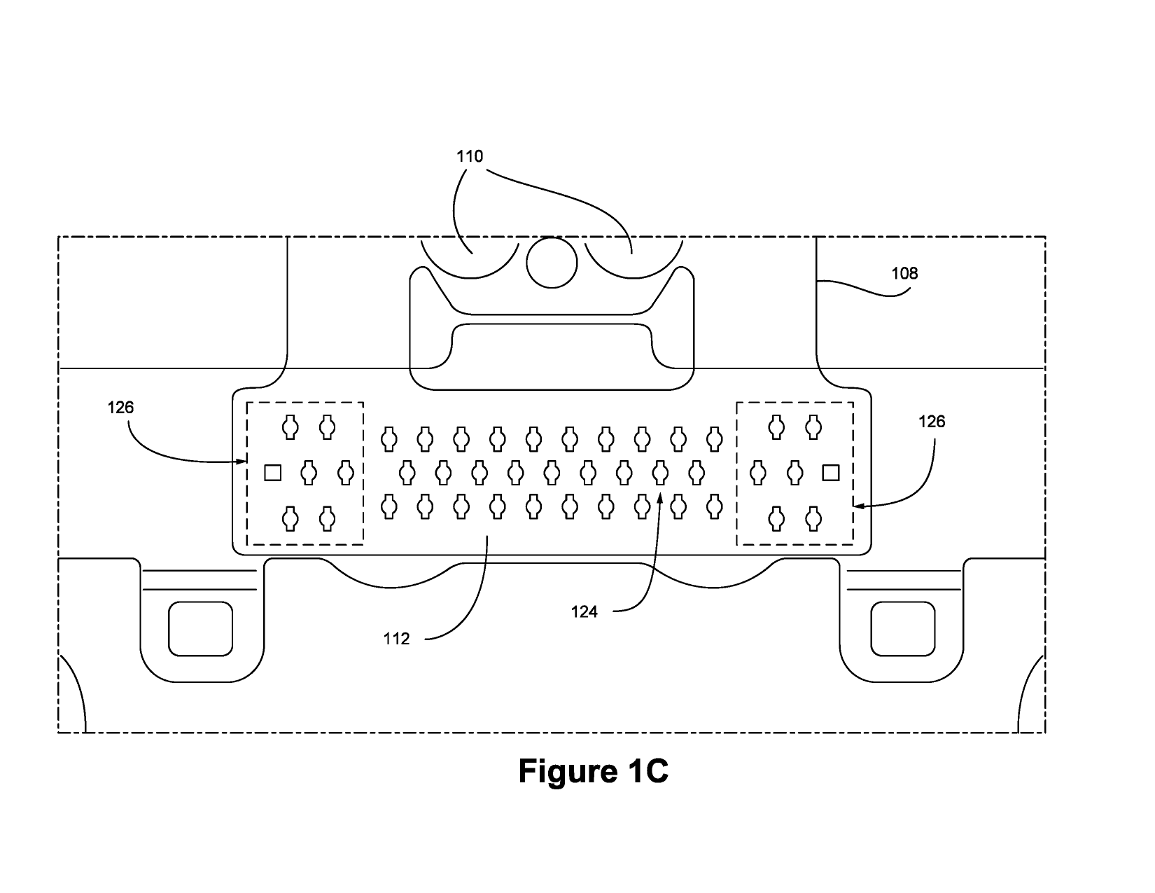

FIG. 1A illustrates an augmented-reality headset 100 with a flexible circuit 102, including a zoomed-in view of a portion of the flexible circuit 102, in accordance with some embodiments. As shown in FIG. 1A, the flexible circuit 102 includes a printed circuit board (“PCB”) 106, an intermediary ribbon cable 108, and/or ribbon cable 104. The intermediary ribbon cable 108 includes one or more battery charging terminals 110. The ribbon cable 104 includes one or more connectors 107 that are configured to connect to one or more batteries, one or more processors, and/or other components of the augmented-reality headset 100. Additionally, the flexible circuit 102 includes an image sensor 105 coupled to the PCB 106. The image sensor 105 is configured to provide image data related to disparity between a first display and a second display.

The flexible circuit 102 is shaped and placed at a nose bridge region and/or the brow region of the augmented-reality headset 100. For example, the PCB 106 is placed in a nose bridge region of the augmented-reality headset 100. In this example, the PCB 106 is placed such that the image sensor is positioned to receive light from the first display and the second display for disparity sensing. Additionally, the intermediary ribbon cable 108 folds around a portion of the bracket 103 such that the battery charging terminals 110 (e.g., spring-loaded pogo pins or other connection types for charging) are positioned at a bottom portion of the nose bridge region. Additionally, the ribbon cable 104 is shaped and placed in a nose bridge region and/or brow region of the augmented-reality headset 100. As shown in FIG. 1A, the ribbon cable 104 is shaped to match a profile (e.g., shape and/or curvature) of the augmented-reality headset 100. In some embodiments, the ribbon cable 104 is further shaped to not interfere with other components, such as display generation components (e.g., projectors, waveguides, and/or other display generation components). For example, the ribbon cable 104 includes one or more bends to be positioned around the display generation components.

According to the embodiment shown in FIG. 1A, the flexible circuit 102 is coupled (e.g., fastened) to a frame 101 via a bracket 103, wherein the bracket 103 is configured to couple to the frame 101 and the PCB 106. The connection between the flexible circuit 102 and the bracket 103 is described in more detail in FIG. 1C. In some embodiments, the flexible circuit 102 is configured to couple to the frame 101 via one or more fastening regions (which are described in more detail with respect to FIG. 1B) or via one or more clips and/or tabs of the frame 101.

The flexible circuit 102 is configured to concurrently receive and transmit information from the image sensor 105 and receive and transmit power from the battery charging terminals 110 to one or more batteries. The one or more batteries are stored in a region of the augmented-reality headset 100 that is distinct from the nose bridge region and/or the brow region.

FIG. 1A also illustrates that flexible circuit 102 a magnetometer 121 which is used as part of the sensor package that delivers world-locked rendering and the personal space user experience.

FIG. 1A also includes a disparity sensor 123 that spans across the nose bridge of the frame 101. The disparity sensor 123 is configured to receive light (e.g., alignment dots that are imperceptible to the wearer) from both a left waveguide 125A and right waveguide 125B. The disparity sensor comprises a mini-waveguide that receives light from the left waveguide and right waveguide and transmits coalesced light to a sensor (e.g., a camera). From the camera data, the coalesced light is analyzed and the differences in the light between the two lenses can be used to determine any disparity between the left waveguide 125A and the right waveguide 125B. Using the determined disparity, the output of the waveguides can be adjusted to correct the disparity (e.g., image outputs from the microLEDs are adjusted to correct for any disparity). In some embodiments, this correction occurs during assembly and at predetermined intervals after production to account for any variations that may occur from aging and use. Components of the disparity sensor can be integrated into the flexible circuit 102, which can include the mini-waveguide, camera for measuring light from the mini-waveguide, disparity sensor circuitry for determining disparity, etc. In some embodiments, components of the disparity sensor 123 are not all located on the flexible circuit 102, e.g., the disparity sensor is on a standalone circuit (e.g., a flexible circuit or non-flexible circuit) separate from the flexible circuit 102, or some of the components are located on the flexible circuit 102 and others on another circuit.

FIG. 1B illustrates the flexible circuit 102 including an intermediary ribbon cable 108, in accordance with some embodiments. The intermediary ribbon cable 108 is configured to wrap around the bracket 107 such that the hot bar connection 112 is underneath (based on the perspective of FIG. 1B) the bracket 107, PCB 106, and/or image sensor 105 and that the battery charging terminals 110 are approximately orthogonal to the bracket 107, PCB 106, image sensor 105, and/or hot bar connection 112. Bending and/or wrapping the intermediary ribbon cable 108 increases the package density of the flexible circuit 102 (e.g., the flexible circuit 102 requires less area within the augmented-reality headset 100).

The ribbon cable 104 of the flexible circuit 102 includes one or more locating tabs (e.g., locating tab 114 and locating tab 116). The locating tabs are configured to be used for locating the flexible circuit 102 during assembly of the flexible circuit. In some embodiments, these locating tabs are removed after the flexible circuit is produced. The flexible circuit also includes slots 117A and 117B which hook onto tangs 119A and 119B (shown in reference to FIG. 1A). The slots 117A and 117B and tangs 119A and 119B interface when the flexible circuit 102 is folded (e.g., as pictured in FIG. 1) and assist in maintaining/holding the folded shape.

FIG. 1C illustrates a hot bar connection of the flexible circuit 102, in accordance with some embodiments. The hot bar connection 112 includes a first plurality of soldered connections 124 for concurrently transmitting power and/or information and a second plurality of soldered connections 126 for reducing a physical load on the first plurality of soldered connections. For example, the first plurality of soldered connections 124 is configured for transmitting power from the battery charging terminals 110 to one or more batteries of the augmented-reality headset 100 and also configured to transmit power from the one or more batterie s to the image sensor 105 and transmit information from the image sensor 105 to one or more processors of the augmented-reality headset 100.

In some embodiments, the second plurality of soldered connections 126 are electrically isolated from the first plurality of soldered connections 124, such that the second plurality provides mechanical support without carrying electrical signals or power.

(A1) In some embodiments, a flex circuit (e.g., flexible circuit 102) of an augmented-reality headset (e.g., augmented-reality headset 100), the flex circuit including a shape that allows for placement of the flex circuit at a nose bridge region of an augmented-reality headset, an image sensor (e.g., image sensor 105) configured to provide image data related to disparity between a first display and a second display of the augmented-reality headset, and circuitry used for charging a battery of the augmented-reality headset. The battery charging terminals (e.g., battery charging terminals 110) of the circuitry are located at the nose bridge regions of the augmented-reality headset.

(A2) In some embodiments of A1, the flex circuit is configured to couple to at least two other flex circuits, and wherein the two other flex circuits are located in respective temple arms of the augmented-reality headset (e.g., additional flex circuits connected via the one or more connectors 107).

(A3) In some embodiments of any of A1-A2, the battery charging terminals are spring loaded pogo pins.

(A4) In some embodiments of any of A1-A3, the battery charging terminals are configured to contact pogo pins of a charging case, charging stand, and/or other charging devices.

(A5) In some embodiments of any of A1-A4, the flex circuit comprises (i) a printed circuit board (e.g., PCB 106) and (ii) a flexible ribbon cable, wherein the flexible ribbon cable is coupled, in part, to the printed circuit board through a hot bar connection (e.g., hot bar connection 112). The hot bar connection includes (i) a plurality of soldered connections for transmitting power and/or information (e.g., a first plurality of soldered connections 124) and (ii) an additional plurality of soldered connections configured to reduce a physical load on the plurality of soldered connections (e.g., a second plurality of soldered connections 126).

(A6) In some embodiments of A1-A5, the flex circuit comprises an intermediary ribbon cable (e.g., intermediary ribbon cable 108) that is coupled between the printed circuit board and the flexible ribbon cable.

(A7) In some embodiments of A1-A6, the intermediary ribbon cable includes the battery charging terminals.

(A8) In some embodiments of A1-A7, the intermediary ribbon cable is configured to wrap around a bracket (e.g., bracket 103) for holding the image sensor.

(A9) In some embodiments of A1-A7, a rigid portion of the flex circuit is configured to couple to bracket that is configured to couple to the nose bridge region of the augmented-reality headset. In some embodiments, the rigid portion of the flex circuit is the PCB 106.

(A10) In some embodiments of A1-A9, the bracket is further configured to couple to the image sensor.

(A11) In some embodiments of A1-A10, the battery of the augmented-reality-headset is located in one or more temple regions, distinct from the nose bridge region, of the augmented-reality headset.

(B1) In accordance with some embodiments, an augmented-reality headset includes a flex circuit configured to be placed within a nose bridge region of the augmented-reality headset. The flex circuit includes a shape that allows for placement of the flex circuit at a nose bridge region of an augmented-reality headset, an image sensor configured to provide image data related to disparity between a first display and a second display, and circuitry used for charging a battery of the augmented-reality headset. The battery charging terminals of the circuitry are located at the nose bridge region of the augmented-reality headset.

(B2) In accordance with some embodiments of B1, the augmented-reality headset includes the features corresponding to any one of A1-A11.

(C1) In accordance with some embodiments, a method of manufacturing a flex circuit for an augmented-reality headset includes coupling a circuit board to an intermediary flex circuit with charging provisions and connecting the intermediary flex circuit to a ribbon cable using a hot bar. Connecting using the hot bar includes connecting a first plurality of soldered connections for transmitting power and/or information and connecting a second plurality of soldered connections configured to reduce a physical load on the plurality of soldered connections.

(C2) In accordance with some embodiments of C1, the flex circuit for the augmented-reality headset includes the features corresponding to any of A1-A11

(D1) In accordance with some embodiments, an electronic device includes a flex circuit and one or more programs, wherein the one or more programs are stored in memory and configured to be executed by one or more processors, the one or more programs including instructions for presenting an augmented-reality at the electronic device and instructions for charging the electronic device that are configured corresponding to any of A1-A11.

(E1) In accordance with some embodiments, a non-transitory computer readable storage medium including instructions that, when executed by a computing device in communication with an augmented-reality headset cause the computing device to present an augmented-reality at the computing device and cause the computing device to charge that are configured corresponding to any of A1-A11.

(F1) In accordance with some embodiments, a method for presenting an augmented-reality at an augmented-reality headset and charging the augmented-reality headset that is configured corresponding to any of A1-A11.

(G1) In accordance with some embodiments, a system that includes one or more wrist-wearable devices and an augmented-reality headset, and the augmented-reality headset is configured corresponding to any of A1-A11.

### Example Extended-Reality Systems

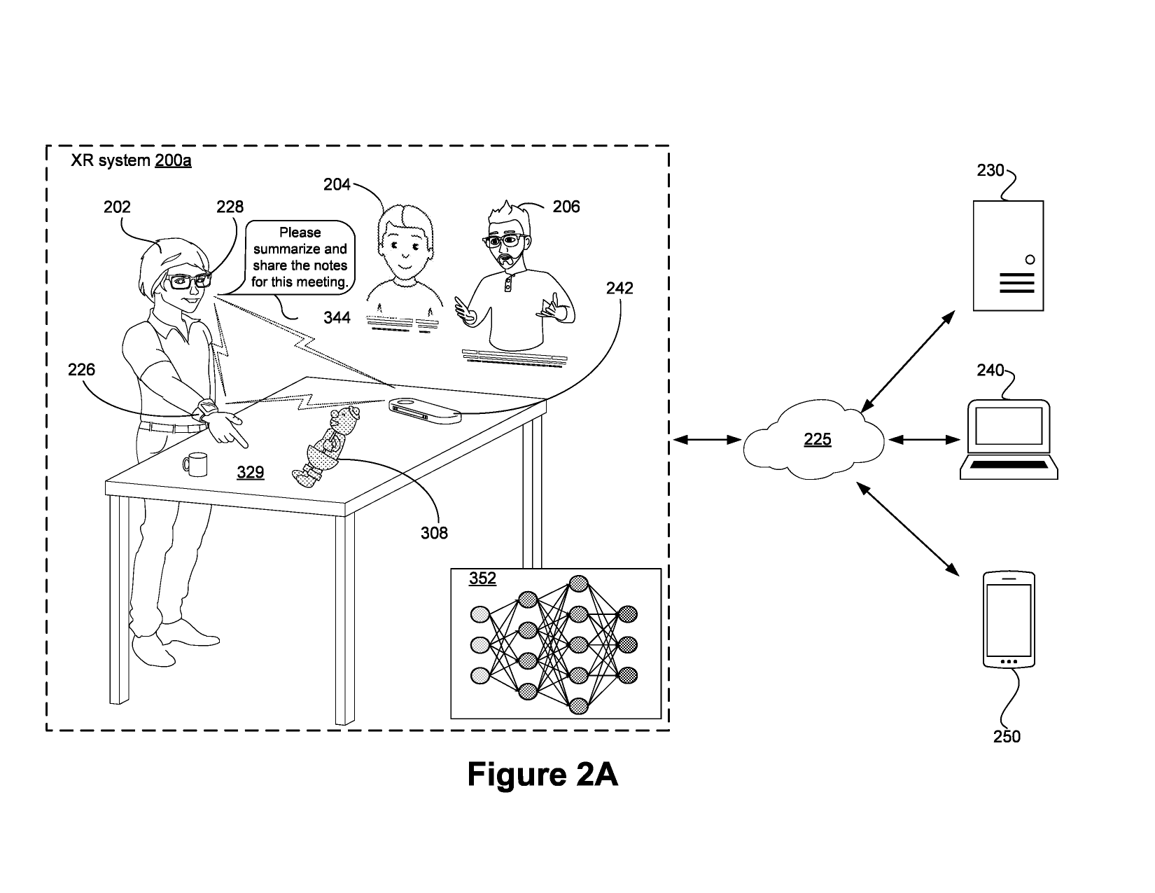

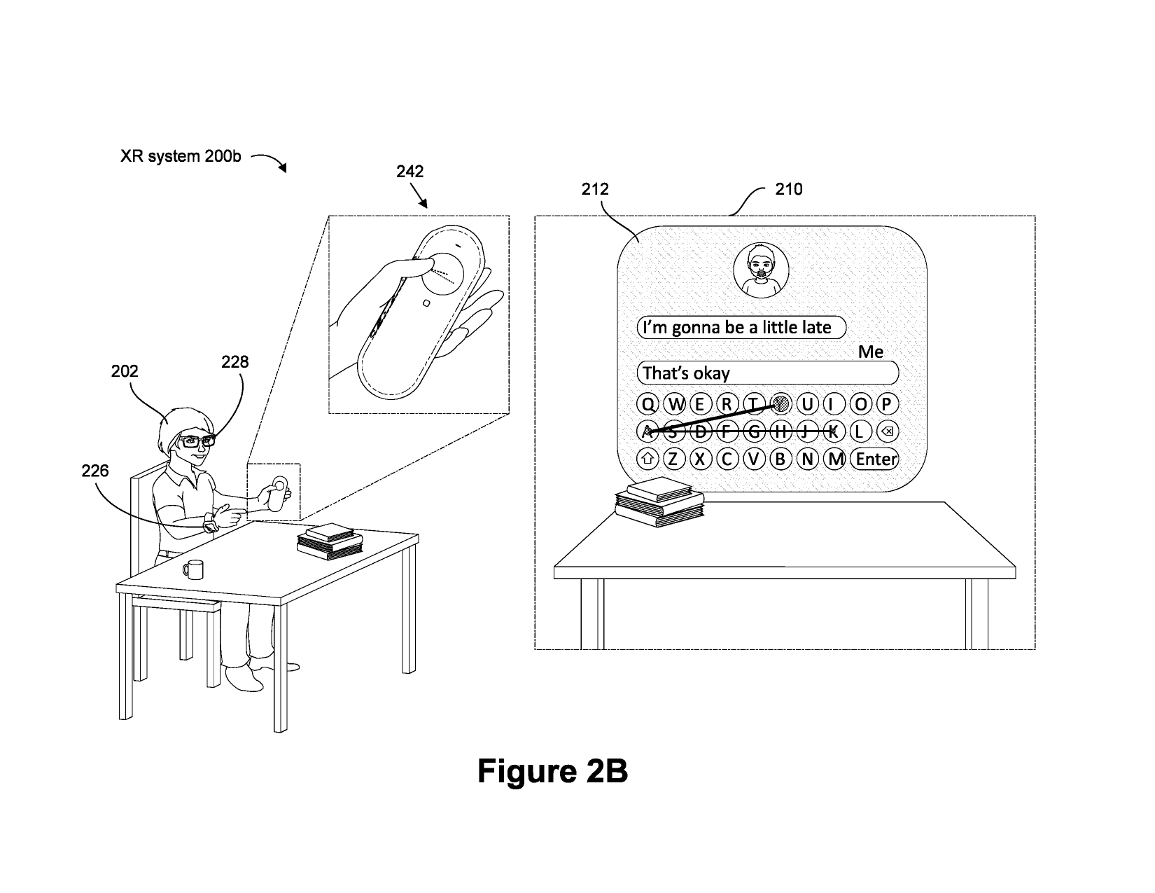

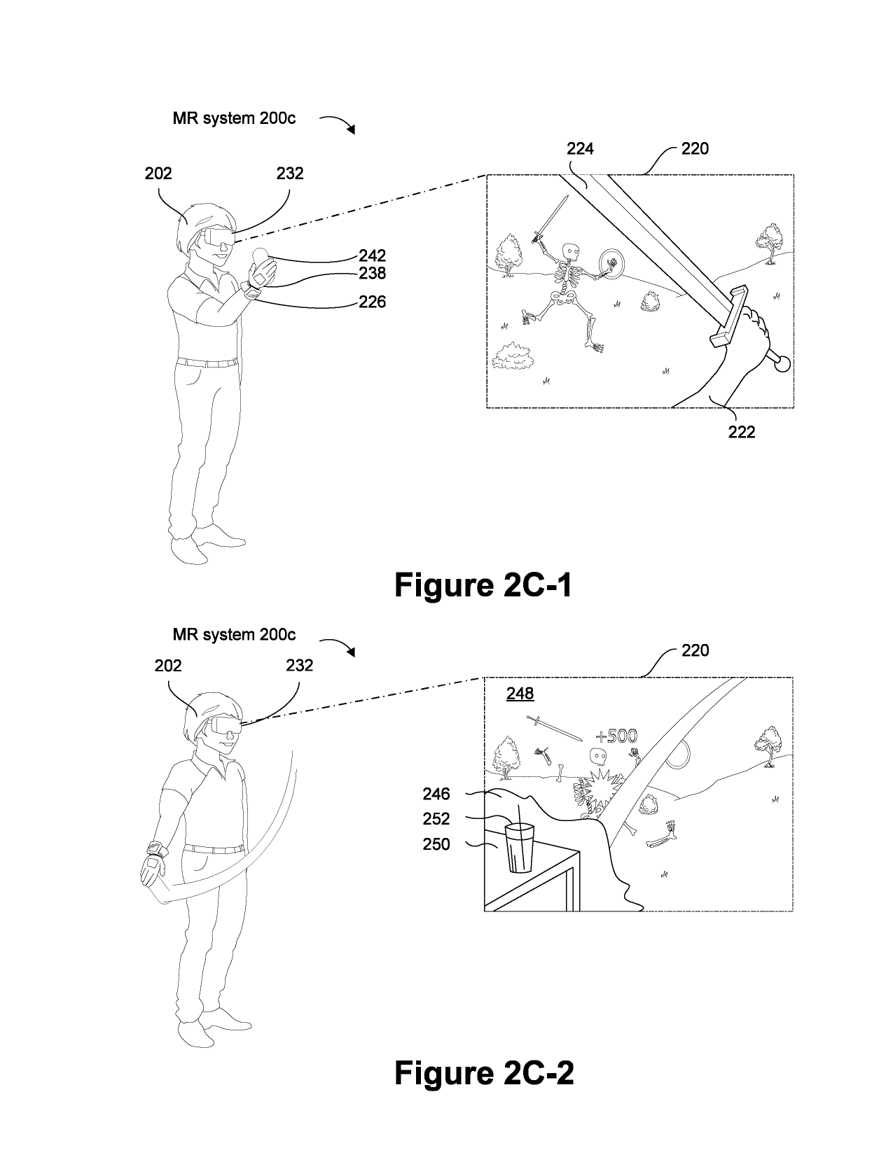

FIGS. 2A, 2B, 2C-1, and 2C-2, illustrate example XR systems that include AR and MR systems, in accordance with some embodiments. FIG. 2A shows a first XR system 200a and first example user interactions using a wrist-wearable device 226, a head-wearable device (e.g., AR device 228), and/or a HIPD 242. FIG. 2B shows a second XR system 200b and second example user interactions using a wrist-wearable device 226, AR device 228, and/or an HIPD 242. FIGS. 2C-1 and 2C-2 show a third MR system 200c and third example user interactions using a wrist-wearable device 226, a head-wearable device (e.g., an MR device such as a VR device), and/or an HIPD 242. As the skilled artisan will appreciate upon reading the descriptions provided herein, the above-example AR and MR systems (described in detail below) can perform various functions and/or operations.

The wrist-wearable device 226, the head-wearable devices, and/or the HIPD 242 can communicatively couple via a network 225 (e.g., cellular, near field, Wi-Fi, personal area network, wireless LAN). Additionally, the wrist-wearable device 226, the head-wearable device, and/or the HIPD 242 can also communicatively couple with one or more servers 230, computers 240 (e.g., laptops, computers), mobile devices 250 (e.g., smartphones, tablets), and/or other electronic devices via the network 225 (e.g., cellular, near field, Wi-Fi, personal area network, wireless LAN). Similarly, a smart textile-based garment, when used, can also communicatively couple with the wrist-wearable device 226, the head-wearable device(s), the HIPD 242, the one or more servers 230, the computers 240, the mobile devices 250, and/or other electronic devices via the network 225 to provide inputs.

Turning to FIG. 2A, a user 202 is shown wearing the wrist-wearable device 226 and the AR device 228 and having the HIPD 242 on their desk. The wrist-wearable device 226, the AR device 228, and the HIPD 242 facilitate user interaction with an AR environment. In particular, as shown by the first AR system 200a, the wrist-wearable device 226, the AR device 228, and/or the HIPD 242 cause presentation of one or more avatars 204, digital representations of contacts 206, and virtual objects 208. As discussed below, the user 202 can interact with the one or more avatars 204, digital representations of the contacts 206, and virtual objects 208 via the wrist-wearable device 226, the AR device 228, and/or the HIPD 242. In addition, the user 202 is also able to directly view physical objects in the environment, such as a physical table 229, through transparent lens(es) and waveguide(s) of the AR device 228. Alternatively, an MR device could be used in place of the AR device 228 and a similar user experience can take place, but the user would not be directly viewing physical objects in the environment, such as table 229, and would instead be presented with a virtual reconstruction of the table 229 produced from one or more sensors of the MR device (e.g., an outward facing camera capable of recording the surrounding environment).

The user 202 can use any of the wrist-wearable device 226, the AR device 228 (e.g., through physical inputs at the AR device and/or built-in motion tracking of a user’s extremities), a smart-textile garment, externally mounted extremity tracking device, the HIPD 242 to provide user inputs, etc. For example, the user 202 can perform one or more hand gestures that are detected by the wrist-wearable device 226 (e.g., using one or more EMG sensors and/or IMUs built into the wrist-wearable device) and/or AR device 228 (e.g., using one or more image sensors or cameras) to provide a user input. Alternatively, or additionally, the user 202 can provide a user input via one or more touch surfaces of the wrist-wearable device 226, the AR device 228, and/or the HIPD 242, and/or voice commands captured by a microphone of the wrist-wearable device 226, the AR device 228, and/or the HIPD 242. The wrist-wearable device 226, the AR device 228, and/or the HIPD 242 include an artificially intelligent digital assistant to help the user in providing a user input (e.g., completing a sequence of operations, suggesting different operations or commands, providing reminders, confirming a command). For example, the digital assistant can be invoked through an input occurring at the AR device 228 (e.g., via an input at a temple arm of the AR device 228). In some embodiments, the user 202 can provide a user input via one or more facial gestures and/or facial expressions. For example, cameras of the wrist-wearable device 226, the AR device 228, and/or the HIPD 242 can track the user 202’s eyes for navigating a user interface.

The wrist-wearable device 226, the AR device 228, and/or the HIPD 242 can operate alone or in conjunction to allow the user 202 to interact with the AR environment. In some embodiments, the HIPD 242 is configured to operate as a central hub or control center for the wrist-wearable device 226, the AR device 228, and/or another communicatively coupled device. For example, the user 202 can provide an input to interact with the AR environment at any of the wrist-wearable device 226, the AR device 228, and/or the HIPD 242, and the HIPD 242 can identify one or more back-end and front-end tasks to cause the performance of the requested interaction and distribute instructions to cause the performance of the one or more back-end and front-end tasks at the wrist-wearable device 226, the AR device 228, and/or the HIPD 242. In some embodiments, a back-end task is a background-processing task that is not perceptible by the user (e.g., rendering content, decompression, compression, application-specific operations), and a front-end task is a user-facing task that is perceptible to the user (e.g., presenting information to the user, providing feedback to the user). The HIPD 242 can perform the back-end tasks and provide the wrist-wearable device 226 and/or the AR device 228 operational data corresponding to the performed back-end tasks such that the wrist-wearable device 226 and/or the AR device 228 can perform the front-end tasks. In this way, the HIPD 242, which has more computational resources and greater thermal headroom than the wrist-wearable device 226 and/or the AR device 228, performs computationally intensive tasks and reduces the computer resource utilization and/or power usage of the wrist-wearable device 226 and/or the AR device 228.

In the example shown by the first AR system 200a, the HIPD 242 identifies one or more back-end tasks and front-end tasks associated with a user request to initiate an AR video call with one or more other users (represented by the avatar 204 and the digital representation of the contact 206) and distributes instructions to cause the performance of the one or more back-end tasks and front-end tasks. In particular, the HIPD 242 performs back-end tasks for processing and/or rendering image data (and other data) associated with the AR video call and provides operational data associated with the performed back-end tasks to the AR device 228 such that the AR device 228 performs front-end tasks for presenting the AR video call (e.g., presenting the avatar 204 and the digital representation of the contact 206).

In some embodiments, the HIPD 242 can operate as a focal or anchor point for causing the presentation of information. This allows the user 202 to be generally aware of where information is presented. For example, as shown in the first AR system 200a, the avatar 204 and the digital representation of the contact 206 are presented above the HIPD 242. In particular, the HIPD 242 and the AR device 228 operate in conjunction to determine a location for presenting the avatar 204 and the digital representation of the contact 206. In some embodiments, information can be presented within a predetermined distance from the HIPD 242 (e.g., within five meters). For example, as shown in the first AR system 200a, virtual object 208 is presented on the desk some distance from the HIPD 242. Similar to the above example, the HIPD 242 and the AR device 228 can operate in conjunction to determine a location for presenting the virtual object 208. Alternatively, in some embodiments, presentation of information is not bound by the HIPD 242. More specifically, the avatar 204, the digital representation of the contact 206, and the virtual object 208 do not have to be presented within a predetermined distance of the HIPD 242. While an AR device 228 is described working with an HIPD, an MR headset can be interacted with in the same way as the AR device 228.

User inputs provided at the wrist-wearable device 226, the AR device 228, and/or the HIPD 242 are coordinated such that the user can use any device to initiate, continue, and/or complete an operation. For example, the user 202 can provide a user input to the AR device 228 to cause the AR device 228 to present the virtual object 208 and, while the virtual object 208 is presented by the AR device 228, the user 202 can provide one or more hand gestures via the wrist-wearable device 226 to interact and/or manipulate the virtual object 208. While an AR device 228 is described working with a wrist-wearable device 226, an MR headset can be interacted with in the same way as the AR device 228.

### Integration of Artificial Intelligence with XR Systems

FIG. 2A illustrates an interaction in which an artificially intelligent virtual assistant can assist in requests made by a user 202. The AI virtual assistant can be used to complete open-ended requests made through natural language inputs by a user 202. For example, in FIG. 2A the user 202 makes an audible request 244 to summarize the conversation and then share the summarized conversation with others in the meeting. In addition, the AI virtual assistant is configured to use sensors of the XR system (e.g., cameras of an XR headset, microphones, and various other sensors of any of the devices in the system) to provide contextual prompts to the user for initiating tasks.

FIG. 2A also illustrates an example neural network 252 used in Artificial Intelligence applications. Uses of Artificial Intelligence (AI) are varied and encompass many different aspects of the devices and systems described herein. AI capabilities cover a diverse range of applications and deepen interactions between the user 202 and user devices (e.g., the AR device 228, an MR device 232, the HIPD 242, the wrist-wearable device 226). The AI discussed herein can be derived using many different training techniques. While the primary AI model example discussed herein is a neural network, other AI models can be used. Non-limiting examples of AI models include artificial neural networks (ANNs), deep neural networks (DNNs), convolution neural networks (CNNs), recurrent neural networks (RNNs), large language models (LLMs), long short-term memory networks, transformer models, decision trees, random forests, support vector machines, k-nearest neighbors, genetic algorithms, Markov models, Bayesian networks, fuzzy logic systems, and deep reinforcement learnings, etc. The AI models can be implemented at one or more of the user devices, and/or any other devices described herein. For devices and systems herein that employ multiple AI models, different models can be used depending on the task. For example, for a natural-language artificially intelligent virtual assistant, an LLM can be used and for the object detection of a physical environment, a DNN can be used instead.

In another example, an AI virtual assistant can include many different AI models and based on the user’s request, multiple AI models may be employed (concurrently, sequentially or a combination thereof). For example, an LLM-based AI model can provide instructions for helping a user follow a recipe and the instructions can be based in part on another AI model that is derived from an ANN, a DNN, an RNN, etc. that is capable of discerning what part of the recipe the user is on (e.g., object and scene detection).

As AI training models evolve, the operations and experiences described herein could potentially be performed with different models other than those listed above, and a person skilled in the art would understand that the list above is non-limiting.

A user 202 can interact with an AI model through natural language inputs captured by a voice sensor, text inputs, or any other input modality that accepts natural language and/or a corresponding voice sensor module. In another instance, input is provided by tracking the eye gaze of a user 202 via a gaze tracker module. Additionally, the AI model can also receive inputs beyond those supplied by a user 202. For example, the AI can generate its response further based on environmental inputs (e.g., temperature data, image data, video data, ambient light data, audio data, GPS location data, inertial measurement (i.e., user motion) data, pattern recognition data, magnetometer data, depth data, pressure data, force data, neuromuscular data, heart rate data, temperature data, sleep data) captured in response to a user request by various types of sensors and/or their corresponding sensor modules. The sensors’ data can be retrieved entirely from a single device (e.g., AR device 228) or from multiple devices that are in communication with each other (e.g., a system that includes at least two of an AR device 228, an MR device 232, the HIPD 242, the wrist-wearable device 226, etc.). The AI model can also access additional information (e.g., one or more servers 230, the computers 240, the mobile devices 250, and/or other electronic devices) via a network 225.

A non-limiting list of AI-enhanced functions includes but is not limited to image recognition, speech recognition (e.g., automatic speech recognition), text recognition (e.g., scene text recognition), pattern recognition, natural language processing and understanding, classification, regression, clustering, anomaly detection, sequence generation, content generation, and optimization. In some embodiments, AI-enhanced functions are fully or partially executed on cloud-computing platforms communicatively coupled to the user devices (e.g., the AR device 228, an MR device 232, the HIPD 242, the wrist-wearable device 226) via the one or more networks. The cloud-computing platforms provide scalable computing resources, distributed computing, managed AI services, interference acceleration, pre-trained models, APIs and/or other resources to support comprehensive computations required by the AI-enhanced function.

Example outputs stemming from the use of an AI model can include natural language responses, mathematical calculations, charts displaying information, audio, images, videos, texts, summaries of meetings, predictive operations based on environmental factors, classifications, pattern recognitions, recommendations, assessments, or other operations. In some embodiments, the generated outputs are stored on local memories of the user devices (e.g., the AR device 228, an MR device 232, the HIPD 242, the wrist-wearable device 226), storage options of the external devices (servers, computers, mobile devices, etc.), and/or storage options of the cloud-computing platforms.

The AI-based outputs can be presented across different modalities (e.g., audio-based, visual-based, haptic-based, and any combination thereof) and across different devices of the XR system described herein. Some visual-based outputs can include the displaying of information on XR augments of an XR headset, user interfaces displayed at a wrist-wearable device, laptop device, mobile device, etc. On devices with or without displays (e.g., HIPD 242), haptic feedback can provide information to the user 202. An AI model can also use the inputs described above to determine the appropriate modality and device(s) to present content to the user (e.g., a user walking on a busy road can be presented with an audio output instead of a visual output to avoid distracting the user 202).

### Example Augmented Reality Interaction

FIG. 2B shows the user 202 wearing the wrist-wearable device 226 and the AR device 228 and holding the HIPD 242. In the second AR system 200b, the wrist-wearable device 226, the AR device 228, and/or the HIPD 242 are used to receive and/or provide one or more messages to a contact of the user 202. In particular, the wrist-wearable device 226, the AR device 228, and/or the HIPD 242 detect and coordinate one or more user inputs to initiate a messaging application and prepare a response to a received message via the messaging application.

In some embodiments, the user 202 initiates, via a user input, an application on the wrist-wearable device 226, the AR device 228, and/or the HIPD 242 that causes the application to initiate on at least one device. For example, in the second AR system 200b the user 202 performs a hand gesture associated with a command for initiating a messaging application (represented by messaging user interface 212); the wrist-wearable device 226 detects the hand gesture; and, based on a determination that the user 202 is wearing the AR device 228, causes the AR device 228 to present a messaging user interface 212 of the messaging application. The AR device 228 can present the messaging user interface 212 to the user 202 via its display (e.g., as shown by user 202’s field of view 210). In some embodiments, the application is initiated and can be run on the device (e.g., the wrist-wearable device 226, the AR device 228, and/or the HIPD 242) that detects the user input to initiate the application, and the device provides another device operational data to cause the presentation of the messaging application. For example, the wrist-wearable device 226 can detect the user input to initiate a messaging application, initiate and run the messaging application, and provide operational data to the AR device 228 and/or the HIPD 242 to cause presentation of the messaging application. Alternatively, the application can be initiated and run at a device other than the device that detected the user input. For example, the wrist-wearable device 226 can detect the hand gesture associated with initiating the messaging application and cause the HIPD 242 to run the messaging application and coordinate the presentation of the messaging application.

Further, the user 202 can provide a user input provided at the wrist-wearable device 226, the AR device 228, and/or the HIPD 242 to continue and/or complete an operation initiated at another device. For example, after initiating the messaging application via the wrist-wearable device 226 and while the AR device 228 presents the messaging user interface 212, the user 202 can provide an input at the HIPD 242 to prepare a response (e.g., shown by the swipe gesture performed on the HIPD 242). The user 202’s gestures performed on the HIPD 242 can be provided and/or displayed on another device. For example, the user 202’s swipe gestures performed on the HIPD 242 are displayed on a virtual keyboard of the messaging user interface 212 displayed by the AR device 228.

In some embodiments, the wrist-wearable device 226, the AR device 228, the HIPD 242, and/or other communicatively coupled devices can present one or more notifications to the user 202. The notification can be an indication of a new message, an incoming call, an application update, a status update, etc. The user 202 can select the notification via the wrist-wearable device 226, the AR device 228, or the HIPD 242 and cause presentation of an application or operation associated with the notification on at least one device. For example, the user 202 can receive a notification that a message was received at the wrist-wearable device 226, the AR device 228, the HIPD 242, and/or other communicatively coupled device and provide a user input at the wrist-wearable device 226, the AR device 228, and/or the HIPD 242 to review the notification, and the device detecting the user input can cause an application associated with the notification to be initiated and/or presented at the wrist-wearable device 226, the AR device 228, and/or the HIPD 242.

While the above example describes coordinated inputs used to interact with a messaging application, the skilled artisan will appreciate upon reading the descriptions that user inputs can be coordinated to interact with any number of applications including, but not limited to, gaming applications, social media applications, camera applications, web-based applications, financial applications, etc. For example, the AR device 228 can present to the user 202 game application data and the HIPD 242 can use a controller to provide inputs to the game. Similarly, the user 202 can use the wrist-wearable device 226 to initiate a camera of the AR device 228, and the user can use the wrist-wearable device 226, the AR device 228, and/or the HIPD 242 to manipulate the image capture (e.g., zoom in or out, apply filters) and capture image data.

While an AR device 228 is shown being capable of certain functions, it is understood that an AR device can be an AR device with varying functionalities based on costs and market demands. For example, an AR device may include a single output modality such as an audio output modality. In another example, the AR device may include a low-fidelity display as one of the output modalities, where simple information (e.g., text and/or low-fidelity images/video) is capable of being presented to the user. In yet another example, the AR device can be configured with face-facing light emitting diodes (LEDs) configured to provide a user with information, e.g., an LED around the right-side lens can illuminate to notify the wearer to turn right while directions are being provided or an LED on the left-side can illuminate to notify the wearer to turn left while directions are being provided. In another embodiment, the AR device can include an outward-facing projector such that information (e.g., text information, media) may be displayed on the palm of a user’s hand or other suitable surface (e.g., a table, whiteboard). In yet another embodiment, information may also be provided by locally dimming portions of a lens to emphasize portions of the environment in which the user’s attention should be directed. Some AR devices can present AR augments either monocularly or binocularly (e.g., an AR augment can be presented at only a single display associated with a single lens as opposed presenting an AR augmented at both lenses to produce a binocular image). In some instances an AR device capable of presenting AR augments binocularly can optionally display AR augments monocularly as well (e.g., for power-saving purposes or other presentation considerations). These examples are non-exhaustive and features of one AR device described above can be combined with features of another AR device described above. While features and experiences of an AR device have been described generally in the preceding sections, it is understood that the described functionalities and experiences can be applied in a similar manner to an MR headset, which is described below in the proceeding sections.

### Example Mixed Reality Interaction

Turning to FIGS. 2C-1 and 2C-2, the user 202 is shown wearing the wrist-wearable device 226 and an MR device 232 (e.g., a device capable of providing either an entirely VR experience or an MR experience that displays object(s) from a physical environment at a display of the device) and holding the HIPD 242. In the third AR system 200c, the wrist-wearable device 226, the MR device 232, and/or the HIPD 242 are used to interact within an MR environment, such as a VR game or other MR/VR application. While the MR device 232 presents a representation of a VR game (e.g., first MR game environment 220) to the user 202, the wrist-wearable device 226, the MR device 232, and/or the HIPD 242 detect and coordinate one or more user inputs to allow the user 202 to interact with the VR game.

In some embodiments, the user 202 can provide a user input via the wrist-wearable device 226, the MR device 232, and/or the HIPD 242 that causes an action in a corresponding MR environment. For example, the user 202 in the third MR system 200c (shown in FIG. 2C-1) raises the HIPD 242 to prepare for a swing in the first MR game environment 220. The MR device 232, responsive to the user 202 raising the HIPD 242, causes the MR representation of the user 222 to perform a similar action (e.g., raise a virtual object, such as a virtual sword 224). In some embodiments, each device uses respective sensor data and/or image data to detect the user input and provide an accurate representation of the user 202’s motion. For example, image sensors (e.g., SLAM cameras or other cameras) of the HIPD 242 can be used to detect a position of the HIPD 242 relative to the user 202’s body such that the virtual object can be positioned appropriately within the first MR game environment 220; sensor data from the wrist-wearable device 226 can be used to detect a velocity at which the user 202 raises the HIPD 242 such that the MR representation of the user 222 and the virtual sword 224 are synchronized with the user 202’s movements; and image sensors of the MR device 232 can be used to represent the user 202’s body, boundary conditions, or real-world objects within the first MR game environment 220.

In FIG. 2C-2, the user 202 performs a downward swing while holding the HIPD 242. The user 202’s downward swing is detected by the wrist-wearable device 226, the MR device 232, and/or the HIPD 242 and a corresponding action is performed in the first MR game environment 220. In some embodiments, the data captured by each device is used to improve the user’s experience within the MR environment. For example, sensor data of the wrist-wearable device 226 can be used to determine a speed and/or force at which the downward swing is performed and image sensors of the HIPD 242 and/or the MR device 232 can be used to determine a location of the swing and how it should be represented in the first MR game environment 220, which, in turn, can be used as inputs for the MR environment (e.g., game mechanics, which can use detected speed, force, locations, and/or aspects of the user 202’s actions to classify a user’s inputs (e.g., user performs a light strike, hard strike, critical strike, glancing strike, miss) or calculate an output (e.g., amount of damage)).

FIG. 2C-2 further illustrates that a portion of the physical environment is reconstructed and displayed at a display of the MR device 232 while the MR game environment 220 is being displayed. In this instance, a reconstruction of the physical environment 246 is displayed in place of a portion of the MR game environment 220 when object(s) in the physical environment are potentially in the path of the user (e.g., a collision with the user and an object in the physical environment are likely). Thus, this example MR game environment 220 includes (i) an immersive VR portion 248 (e.g., an environment that does not have a corollary counterpart in a nearby physical environment) and (ii) a reconstruction of the physical environment 246 (e.g., table 250 and cup 252). While the example shown here is an MR environment that shows a reconstruction of the physical environment to avoid collisions, other uses of reconstructions of the physical environment can be used, such as defining features of the virtual environment based on the surrounding physical environment (e.g., a virtual column can be placed based on an object in the surrounding physical environment (e.g., a tree)).

While the wrist-wearable device 226, the MR device 232, and/or the HIPD 242 are described as detecting user inputs, in some embodiments, user inputs are detected at a single device (with the single device being responsible for distributing signals to the other devices for performing the user input). For example, the HIPD 242 can operate an application for generating the first MR game environment 220 and provide the MR device 232 with corresponding data for causing the presentation of the first MR game environment 220, as well as detect the user 202’s movements (while holding the HIPD 242) to cause the performance of corresponding actions within the first MR game environment 220. Additionally or alternatively, in some embodiments, operational data (e.g., sensor data, image data, application data, device data, and/or other data) of one or more devices is provided to a single device (e.g., the HIPD 242) to process the operational data and cause respective devices to perform an action associated with processed operational data.

In some embodiments, the user 202 can wear a wrist-wearable device 226, wear an MR device 232, wear smart textile-based garments 238 (e.g., wearable haptic gloves), and/or hold an HIPD 242 device. In this embodiment, the wrist-wearable device 226, the MR device 232, and/or the smart textile-based garments 238 are used to interact within an MR environment (e.g., any AR or MR system described above in reference to FIGS. 2A-2B). While the MR device 232 presents a representation of an MR game (e.g., second MR game environment 220) to the user 202, the wrist-wearable device 226, the MR device 232, and/or the smart textile-based garments 238 detect and coordinate one or more user inputs to allow the user 202 to interact with the MR environment.

In some embodiments, the user 202 can provide a user input via the wrist-wearable device 226, an HIPD 242, the MR device 232, and/or the smart textile-based garments 238 that causes an action in a corresponding MR environment. In some embodiments, each device uses respective sensor data and/or image data to detect the user input and provide an accurate representation of the user 202’s motion. While four different input devices are shown (e.g., a wrist-wearable device 226, an MR device 232, an HIPD 242, and a smart textile-based garment 238) each one of these input devices entirely on its own can provide inputs for fully interacting with the MR environment. For example, the wrist-wearable device can provide sufficient inputs on its own for interacting with the MR environment. In some embodiments, if multiple input devices are used (e.g., a wrist-wearable device and the smart textile-based garment 238) sensor fusion can be utilized to ensure inputs are correct. While multiple input devices are described, it is understood that other input devices can be used in conjunction or on their own instead, such as but not limited to external motion-tracking cameras, other wearable devices fitted to different parts of a user, apparatuses that allow for a user to experience walking in an MR environment while remaining substantially stationary in the physical environment, etc.

As described above, the data captured by each device is used to improve the user’s experience within the MR environment. Although not shown, the smart textile-based garments 238 can be used in conjunction with an MR device and/or an HIPD 242.

While some experiences are described as occurring on an AR device and other experiences are described as occurring on an MR device, one skilled in the art would appreciate that experiences can be ported over from an MR device to an AR device, and vice versa.

Some definitions of devices and components that can be included in some or all of the example devices discussed are defined here for ease of reference. A skilled artisan will appreciate that certain types of the components described may be more suitable for a particular set of devices, and less suitable for a different set of devices. But subsequent reference to the components defined here should be considered to be encompassed by the definitions provided.

In some embodiments example devices and systems, including electronic devices and systems, will be discussed. Such example devices and systems are not intended to be limiting, and one of skill in the art will understand that alternative devices and systems to the example devices and systems described herein may be used to perform the operations and construct the systems and devices that are described herein.

As described herein, an electronic device is a device that uses electrical energy to perform a specific function. It can be any physical object that contains electronic components such as transistors, resistors, capacitors, diodes, and integrated circuits. Examples of electronic devices include smartphones, laptops, digital cameras, televisions, gaming consoles, and music players, as well as the example electronic devices discussed herein. As described herein, an intermediary electronic device is a device that sits between two other electronic devices, and/or a subset of components of one or more electronic devices and facilitates communication, and/or data processing and/or data transfer between the respective electronic devices and/or electronic components.

The foregoing descriptions of FIGS. 2A–2C-2 provided above are intended to augment the description provided in reference to FIGS. 1A-1C. While terms in the following description may not be identical to terms used in the foregoing description, a person having ordinary skill in the art would understand these terms to have the same meaning.

Any data collection performed by the devices described herein and/or any devices configured to perform or cause the performance of the different embodiments described above in reference to any of the Figures, hereinafter the “devices,” is done with user consent and in a manner that is consistent with all applicable privacy laws. Users are given options to allow the devices to collect data, as well as the option to limit or deny collection of data by the devices. A user is able to opt in or opt out of any data collection at any time. Further, users are given the option to request the removal of any collected data.

It will be understood that, although the terms “first,” “second,” etc. may be used herein to describe various elements, these elements should not be limited by these terms. These terms are only used to distinguish one element from another.

The terminology used herein is for the purpose of describing particular embodiments only and is not intended to be limiting of the claims. As used in the description of the embodiments and the appended claims, the singular forms “a,” “an” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As used herein, the term “if” can be construed to mean “when” or “upon” or “in response to determining” or “in accordance with a determination” or “in response to detecting,” that a stated condition precedent is true, depending on the context. Similarly, the phrase “if it is determined [that a stated condition precedent is true]” or “if [a stated condition precedent is true]” or “when [a stated condition precedent is true]” can be construed to mean “upon determining” or “in response to determining” or “in accordance with a determination” or “upon detecting” or “in response to detecting” that the stated condition precedent is true, depending on the context.

The foregoing description, for purpose of explanation, has been described with reference to specific embodiments. However, the illustrative discussions above are not intended to be exhaustive or to limit the claims to the precise forms disclosed. Many modifications and variations are possible in view of the above teachings. The embodiments were chosen and described in order to best explain principles of operation and practical applications, to thereby enable others skilled in the art.

What is claimed is:

1. A flex circuit of an augmented-reality headset, the flex circuit comprising:
a shape that allows for placement of the flex circuit at a nose-bridge region of an augmented-reality headset;
a connection to an image sensor configured to provide image data related to disparity between a first display and a second display of the augmented-reality headset; and
circuitry used for charging a battery of the augmented-reality headset, wherein battery charging terminals of the circuitry are located at the nose-bridge region of the augmented-reality headset.

2. The flex circuit of claim 1, wherein:
the flex circuit comprises (i) a printed circuit board and (ii) a flexible printed circuit, wherein the flexible printed circuit is coupled, in part, to the printed circuit board through a hot bar connection, and
the hot bar connection includes (i) a plurality of soldered connections for transmitting power and/or information and (ii) a second plurality of soldered connections configured to reduce a mechanical load on the plurality of soldered connections.

3. The flex circuit of claim 2, wherein the second plurality of soldered connections is electrically isolated from the plurality of soldered connections.

4. The flex circuit of claim 2, wherein the printed circuit board is configured to:
couple to the nose-bridge region of the augmented-reality headset; and
couple to the image sensor.

5. The flex circuit of claim 2, further comprising an intermediary printed circuit coupled between the printed circuit board and the flexible printed circuit, and wherein:
the intermediary printed circuit includes the battery charging terminals; and
the intermediary printed circuit is configured to wrap around a bracket for holding the image sensor.

6. The flex circuit of claim 5, wherein:
the bracket is coupled to a light combiner that is configured to gather the image data from each of the first display and the second display of the augmented-reality headset;
the image sensor is optically coupled to the light combiner to receive the image data from the first display and the second display.

7. The flex circuit of claim 1, wherein:
the battery of the augmented-reality headset is located in a temple arm of the augmented-reality headset; and
the flex circuit is configured to couple to a second flex circuit coupled to the battery and located in the temple arm.

8. The flex circuit of claim 1, wherein:
the battery charging terminals are spring-loaded pogo pins; or
the battery charging terminals are contact pads that are configured to contact pogo pins of a charging case.

9. The flex circuit of claim 1, wherein the first display and the second display of the augmented-reality headset are configured to present an augmented-reality experience at the augmented-reality headset.

10. A pair of smart glasses, comprising:
a flex circuit disposed within a nose-bridge region of the smart glasses, wherein the flex circuit includes:
a shape that allows for placement of the flex circuit at a nose-bridge region of an smart glasses;
a connection to an image sensor configured to provide image data related to disparity between a first display and a second display of the smart glasses; and
circuitry used for charging a battery of the smart glasses, wherein battery charging terminals of the circuitry are located at the nose-bridge region of the smart glasses.

11. The smart glasses of claim 10, wherein:
the flex circuit comprises (i) a printed circuit board and (ii) a flexible printed circuit, wherein the flexible printed circuit is coupled, in part, to the printed circuit board through a hot bar connection, and
the hot bar connection includes (i) a plurality of soldered connections for transmitting power and/or information and (ii) a second plurality of soldered connections configured to reduce a mechanical load on the plurality of soldered connections.

12. The smart glasses of claim 11, wherein the second plurality of soldered connections are electrically isolated from the plurality of soldered connections.

13. The smart glasses of claim 11, wherein the printed circuit board is configured to:
couple to the nose-bridge region of the smart glasses; and
couple to the image sensor.

14. The smart glasses of claim 11, further comprising an intermediary printed circuit coupled between the printed circuit board and the flexible printed circuit, and wherein:
the intermediary printed circuit includes the battery charging terminals; and
the intermediary printed circuit is configured to wrap around a bracket for holding the image sensor.

15. The smart glasses of claim 14, wherein:
the bracket is coupled to a light combiner that is configured to gather light from the first display and the second display of the smart glasses;
the image sensor is optically coupled to the light combiner to receive the light from the first display and the second display.

16. The smart glasses of claim 10, wherein:
the battery of the smart glasses is located in a temple arm of the smart glasses; and
the flex circuit is configured to couple to a second flex circuit coupled to the battery and located in the temple arm.

17. The smart glasses of claim 10, wherein:
the battery charging terminals are spring-loaded pogo pins; or
the battery charging terminals are contact pads that are configured to contact pogo pins of a charging case.

18. The smart glasses of claim 10, wherein the first display and the second display of the smart glasses are configured to present an augmented-reality experience at the smart glasses.

19. A method, comprising:
presenting an augmented-reality experience via a first display and a second display of a pair of smart glasses, wherein the pair of smart glasses comprises:
a flex circuit disposed within a nose-bridge region of the smart glasses, wherein the flex circuit includes:
a shape that allows for placement of the flex circuit at a nose-bridge region of an smart glasses;
a connection to an image sensor configured to provide image data related to disparity between the first display and the second display of the smart glasses; and
circuitry used for charging a battery of the smart glasses, wherein battery charging terminals of the circuitry are located at the nose-bridge region of the smart glasses.

20. The method of claim 19, further comprising:
determining, based on image data provided by the image sensor, a disparity between the first display and the second display of the smart glasses; and
reducing an amount of disparity associated with the augmented-reality experience that is outputted via the first display and the second display.
